(19) United States
(12) Patent Application Publication
(10) Pub. No.: US 2025/0139312 A1
(43) Pub. Date: May 1, 2025

(54) Auto-Smasher for Real-World Contextual Visualization

(71) Applicant: PassiveLogic, Inc., Holladay, UT (US)

(72) Inventor: Troy Aaron Harvey, Brighton, UT (US)

(21) Appl. No.: 18/496,491

(22) Filed: Oct. 27, 2023

(51) Int. Cl. G06F 30/13; G06T 17/05

(52) U.S. Cl. CPC G06F 30/13; G06T 17/05

(57) ABSTRACT

Various embodiments relate to a method, apparatus, and machine-readable storage medium including one or more of the following: identifying a location for the new virtual object within the virtual environment; identifying a footprint associated with the new virtual object for placement at the location; setting a height of the virtual environment within the footprint to a height level with the footprint to produce a modified virtual environment; placing the new virtual object within the footprint; and rendering the modified virtual environment and new virtual object for display to a user via an interface scene.

### TECHNICAL FIELD

Various embodiments described herein relate to design and simulation tools and more particularly, but not exclusively, to tools for automatic placement of a newly-designed building in a recreation of a real-world environment.

### BACKGROUND

In building computer aided design programs, it is often useful to visualize not just the building being designed, but also the surrounding area. This enables the designer to view the building in context, and to adjust its location on the desired plot for various reasons such as accounting for sunlight exposure, accessibility, and aesthetic reasons. This process, however, multiplies the amount of work the designer must do, as the designer is now creating not only the subject building, but also the surrounding building exteriors, trees and landscaping, and all other items in the surrounding area.

### SUMMARY

According to the foregoing, it would be desirable to provide a method of viewing or simulating a building (or other virtual object) in the context of its intended virtual environment in a way that reduces the amount of work the designer must do to achieve the result. According to various embodiments, a method is described to both automatically generate the virtual environment for the subject of design and to automatically prepare a site for the location of that subject within the virtual environment. Following these approaches, various embodiments provide an enhanced user experience that greatly reduces the amount of work a user must do for site planning. Various other technical benefits will be apparent in view of the following description.

Various embodiments described herein relate to a method for placement of a new virtual object in a virtual environment, the method including one or more of the following: identifying a location for the new virtual object within the virtual environment; identifying a footprint associated with the new virtual object for placement at the location; setting a height of the virtual environment within the footprint to a height level with the footprint to produce a modified virtual environment; placing the new virtual object within the footprint; and rendering the modified virtual environment and new virtual object for display to a user via an interface scene.

Various embodiments described herein relate to a non-transitory machine-readable medium encoded with instructions for execution by a processor for placement of a new virtual object in a virtual environment, the non-transitory machine-readable medium including one or more of the following: instructions for identifying a location for the new virtual object within the virtual environment; instructions for identifying a footprint associated with the new virtual object for placement at the location; instructions for setting a height of the virtual environment within the footprint to a height level with the footprint to produce a modified virtual environment; instructions for placing the new virtual object within the footprint; and instructions for rendering the modified virtual environment and new virtual object for display to a user via an interface scene.

Various embodiments described herein relate to a device for rendering a new virtual object within a virtual environment, the device comprising: a memory storing descriptions of the new virtual object and the virtual environment; and a processor in communication with the memory configured to: identify a location for the new virtual object within the virtual environment; identify a footprint associated with the new virtual object for placement at the location; set a height of the virtual environment within the footprint to a height level with the footprint to produce a modified virtual environment; place the new virtual object within the footprint; and render the modified virtual environment and new virtual object for display to a user via an interface scene.

Various embodiments are described wherein setting the height of the virtual environment comprises removing at least one pre-existing virtual object of the virtual environment that is located within the footprint.

Various embodiments are described wherein the step of rendering comprises: animating the new virtual object virtually falling onto the location within the virtual environment; and animating the removal of the at least one pre-existing virtual object.

Various embodiments are described wherein rendering the virtual environment and new virtual object comprises additionally rendering the footprint and the method further comprises: receiving, from a user via the interface scene, a change to at least one of a dimension, size, orientation, shape, and location of the footprint to product a modified footprint; and repeating the step of setting the height of the virtual environment with respect to the modified footprint.

Various embodiments additionally include receiving, from a user via the interface scene, a change to a parameter of the virtual object comprising at least one of a location and an orientation within the footprint to produce a modified parameter; and moving the new virtual object within the footprint based on the modified parameter.

Various embodiments are described wherein the new virtual object is a virtual building designed by the user and the virtual environment generated based on at least one of real world map data and real world terrain data.

Various embodiments additionally include performing a simulation with respect to the virtual object and the modified virtual environment; and displaying a result of the simulation to the user via the interface scene.

### BRIEF DESCRIPTION OF THE DRAWINGS

In order to better understand various example embodiments, reference is made to the accompanying drawings, wherein:

FIG. 1 illustrates an example system for implementation of various embodiments;

FIG. 2 illustrates an example device for implementing a digital twin application suite;

FIG. 3 illustrates an example digital twin 300 for construction by or use in various embodiments;

FIG. 4 illustrates an example graphical user interface for visualizing a site;

FIG. 5A illustrates a first example graphical user interface for visualizing an autosmasher;

FIG. 5B illustrates a second example graphical user interface for visualizing an autosmasher;

FIG. 5C illustrates a third example graphical user interface for visualizing an autosmasher;

FIG. 6 illustrates an example graphical user interface for modifying an autosmasher;

FIG. 7 illustrates an example hardware device for implementing a digital twin application device;

FIG. 8 illustrates an example method for rendering an environment; and

FIG. 9 illustrates an example method for autosmashing an environment rendering.

### DETAILED DESCRIPTION

The description and drawings presented herein illustrate various principles. It will be appreciated that those skilled in the art will be able to devise various arrangements that, although not explicitly described or shown herein, embody these principles and are included within the scope of this disclosure. As used herein, the term, “or,” as used herein, refers to a non-exclusive or (i.e., and/or), unless otherwise indicated (e.g., “or else” or “or in the alternative”). Additionally, the various embodiments described herein are not necessarily mutually exclusive and may be combined to produce additional embodiments that incorporate the principles described herein.

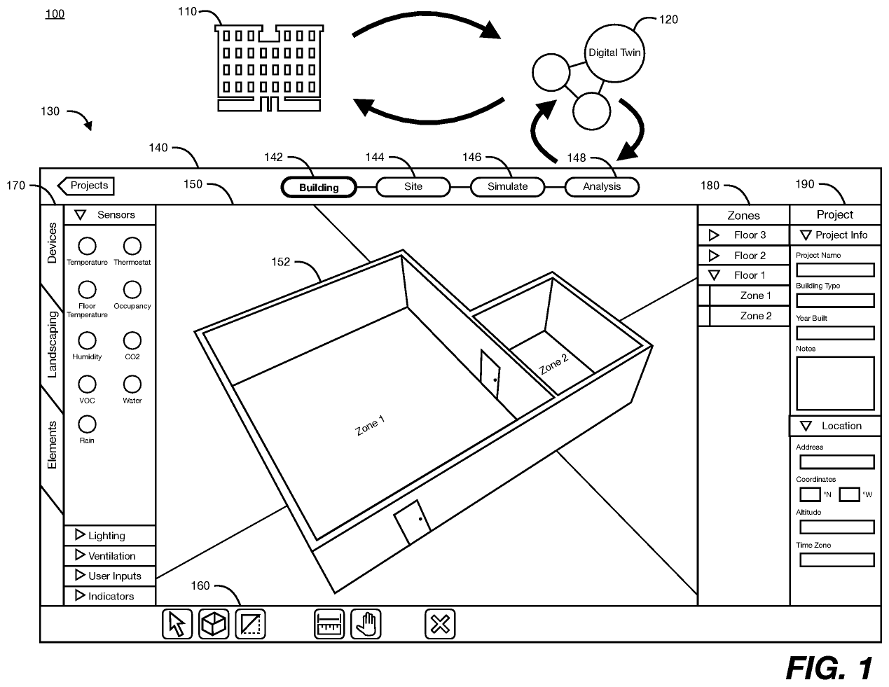

FIG. 1 illustrates an example system 100 for implementation of various embodiments. As shown, the system 100 may include an environment 110, at least some aspect of which is modeled by a digital twin 120. The digital twin 120, in turn, interacts with a digital twin application suite 130 for providing a user with various means for interaction with the digital twin 120 and for gaining insights into the real-world environment 110. According to one specific set of examples, the environment 110 is a building while the digital twin 120 models various aspects of that building such as, for example, the building structure, its climate conditions (e.g., temperature, humidity, etc.), and a system of controllable heating, ventilation, and air conditioning (HVAC) equipment.

While various embodiments disclosed herein will be described in the context of such an HVAC application or in the context of building design and analysis, it will be apparent that the techniques described herein may be applied to other applications including, for example, applications for controlling a lighting system, a security system, an automated irrigation or other agricultural system, a power distribution system, a manufacturing or other industrial system, or virtually any other system that may be controlled. Further, the techniques and embodiments may be applied other applications outside the context of controlled systems or environments 110 that are buildings. Virtually any entity or object that may be modeled by a digital twin may benefit from the techniques disclosed herein. Various modifications to adapt the teachings and embodiments to use in such other applications will be apparent.

The digital twin 120 is a digital representation of one or more aspects of the environment 110. In various embodiments, the digital twin 120 is implemented as a heterogenous, omnidirectional neural network. As such, the digital twin 120 may provide more than a mere description of the environment 110 and rather may additionally be trainable, computable, queryable, and inferencable, as will be described in greater detail below. In some embodiments, one or more processes continually, periodically, or on some other iterative basis adapts the digital twin 120 to better match observations from the environment 110. For example, the environment 110 may be outfitted with one or more temperature sensors that provide data to a building controller (not shown), which then uses this information to train the digital twin to better reflect the current state or operation of the environment. In this way, the digital twin is a “living” digital twin that, even after initial creation, continues to adapt itself to match the environment 110, including adapting to changes such as system degradation or changes (e.g., permanent changes such as removing a wall and transient changes such as opening a window).

Various embodiments of the techniques described herein may use alternative types of digital twins than the heterogenous neural network type described in most examples herein. For example, in some embodiments, the digital twin 120 may not be organized as a neural network and may, instead, be arranged as another type of model for one or more components of the environment 110. In some such embodiments, the digital twin 120 may be a database or other data structure that simply stores descriptions of the system aspects, environmental features, or devices being modeled, such that other software has access to data representative of the real world objects and entities, or their respective arrangements, as the software performs its functions.

The digital twin application suite 130 may provide a collection of tools for interacting with the digital twin 120 such as, for example, tools for creating and modifying the digital twin 120; using the digital twin to design a building manually or using generative methods 120; using the digital twin to perform site planning and analysis for the building 120; using the digital twin to perform simulations of the environment 110; or using the digital twin to provide an interactive live building information model (BIM) of the environment. It will be understood that while the application suite 130 is depicted here as a single user interface that the application suite 130 includes a mix of hardware and software, including software for performing various backend functions and for providing multiple different interface scenes (such as the one shown) for enabling the user to interact with the digital twin 120 in different ways and using different tools and applications in the application suite 130.

As shown, the digital twin application suite 130 currently displays an interface scene for providing user access to and interaction with a building design application. This building design application may be used for various purposes such as for designing a building to be built (e.g., before the building 110 has been built) or for designing renovations or retrofits to an existing building. As will be explained in greater detail below, the design of a building using this building design application drives creation or modification of the digital twin 120 itself. As such, the building design application may also be used as a digital twin creator, to capture the structure of an existing building 110 in the digital twin 120, so that the digital twin 120 can be used by other applications (including those provided by the digital twin application suite 130 or by other external applications such as a controller that autonomously controls the HVAC or other controllable system of the environment 110).

The digital twin application suite's 130 current interface scene includes a collection of panels, including a navigation panel 140, a workspace 150, a tool panel 160, a library panel 170, a exploration panel 170, and a project information panel 180. Various alternative embodiments will include a different set of panels or other overall graphical interface designs that enable access to the applications, tools, and techniques described herein.

As noted, the digital twin application suite 130 may display only one interface scene of a multi-interface suite or software package. The navigation panel 140 includes a set of ordered indicators 142, 144, 146, 148 conveying a workflow for design, simulation, and analysis using a digital twin 120 and the various applications of the application suite 130. These include a Building indicator 142 associated with a building design application and associated interface scene(s); a Site indicator 144 associated with a site planning application and associated interface scene(s); a Simulate indicator 146 associated with a simulation application and associated interface scene(s); and an Analysis indicator 148 associated with a live building analysis application and associated interface scene(s). The Building indicator 142 has an altered appearance compared to the other indicators 144, 146, 148 (here, bold text and thick outer lines, but any alteration can be used) to indicate that it is the presently active step or application, and is associated with the presently-displayed interface scene. In some embodiments, visual or other cues can be used to indicate additional workflow information: that the steps associated with indicators have been completed, that the current step is ready or not ready to be completed, that there is a problem with a step associated with an indicator, etc. In some embodiments, the indicators 142, 144, 146, 148 may be interface buttons that enable, upon user click, tap, or other selection, the user to change the interface scene to another interface scene associated with the selected indicator 142, 144, 146, 148.

The workspace 150 includes an area where a user may view, explore, construct, or modify the building (or other entities or objects to be represented by the digital twin 120). As shown, the workspace 150 already displays a 3D rendering 152 of a building including at least a single floor and two rooms (labeled zone 1 and zone 2). Various controls (not shown) may be provided to the user for altering the user's view of the building rendering 152 within the workspace 150. For example, the user may be able to rotate, zoom, or pan the view of the building rendering 152 in one or more dimensions using mouse controls (click and drag, mouse wheel, etc.) or interface controls that can be selected. The user may also be provided with similar controls for altering the display of the building rendering, such as toggling between 2D and 3D views or changing the portion of the building that is rendered (e.g., rendering alternative or additional floors from a multi-floor building).

The tool panel 160 includes a number of buttons that provide access to a variety of interface tools for interacting with the workspace 150 or building rendering 152. For example, buttons may be provided for one or more of the previously-described interactions for changing the view of the building rendering 152. As another example, the tool panel 160 may provide buttons for accessing tools to modify the building rendering 152 itself. For example, tools may be accessible via the tool bar 160 for adding, deleting, or changing the dimensions of zones in the building rendering 152; adding, deleting, or changing structural features such as doors and windows; adding, deleting, or changing non-structural assets such as chairs and shelves; or for specifying properties of any of the foregoing.

The library panel 170 includes multiple expandable categories of items that may be dragged and dropped by the user into the workspace for addition to the building rendering 152. Such items may be functional, such as various devices for sensing conditions of the building, providing lighting and ventilation, receiving system input from users, or providing output or other indicators to users. Other items may be purely aesthetic or may provide other information about the building (e.g., placement of shelves may help to determine an amount of shelf space). As before, placement of these items may indicate that these items are expected to be installed in the environment 110 or are already installed in the environment 110 so as to make the digital twin 120 aware of their presence.

While the foregoing examples speak of user tools for creating or making modifications to the building rendering 152, in various embodiments this functionality occurs by way of creation or modification of the digital twin 120. That is, when a user interacts with the workspace to create, e.g., a new zone, digital twin application suite 130 updates the digital twin 120 to include the new zone and new walls surrounding the zone, as well as any other appropriate modifications to other aspects of the digital twin (e.g., conversion of exterior walls to interior walls). Then, once the digital twin 120 is updated, the digital twin application suite 130 renders the currently displayed portion of the digital twin 120 into the building rendering 152, thereby visually reflecting the changes made by the user. Thus, not only does the building design application of the digital twin application suite 130 provide a computer aided design (CAD) tool, it simultaneously facilitates creation and modification of the digital twin 120 for use by other applications or to better inform the operation of the CAD functionality itself (e.g., by providing immediate feedback on structural feasibility at the time of design or by providing generative design functionality to automatically create various structures which may be based on user-provided constraints or preferences).

The exploration panel 180 provides a tree view of the digital twin to enable the user to see a more complete view of the digital twin or to enable easy navigation. For example, if the full digital twin is a multi-story building, the exploration panel 180 may provide access to all floors and zones, where the workspace is only capable of displaying a limited number of floors at the level of detail desired by the user.

The project information panel 190 provides the user with interface elements for defining properties of the build or project to which the building is associated. For example, the user may be able to define a project name, a building type, a year of construction, and various notes about the project. This meta-data may be useful for the user in managing a portfolio of such projects. The project information panel 190 may also allow the user to specify the location of the building. Such information may be used by other applications such as site planning (e.g., to digitally recreate the real world environment where the building is located or will be built) or simulation (e.g., to simulate the typical weather and sun exposure for the building). Various other applications for the digital twin application suite 130 will be described below as appropriate to illustrate the techniques disclosed herein.

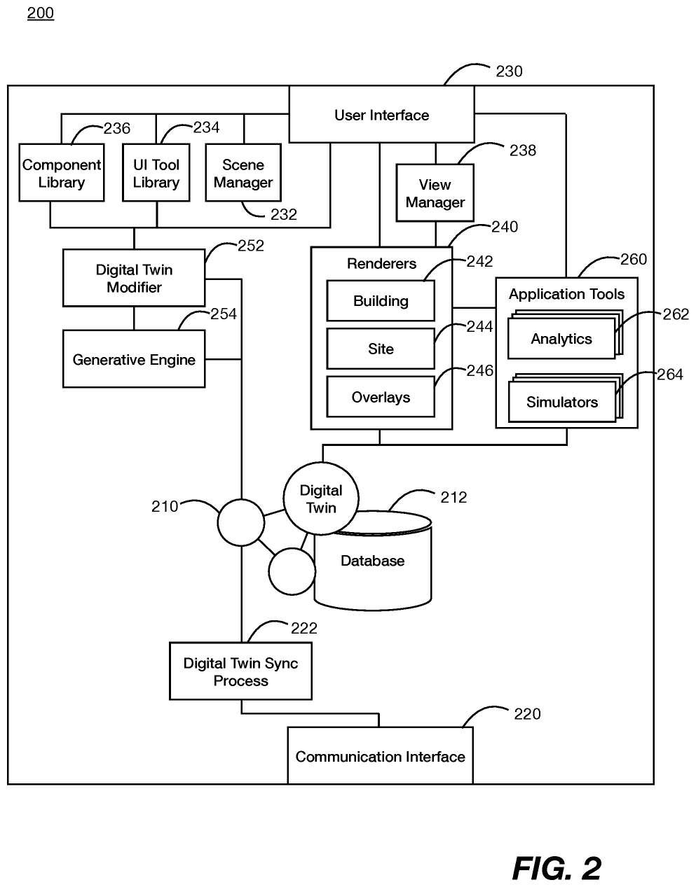

FIG. 2 illustrates an example device for implementing a digital twin application suite 200. The digital twin application device 200 may correspond to the device that provides digital twin application suite 130 and, as such, may provide a user with access to one or more applications for interacting with a digital twin.

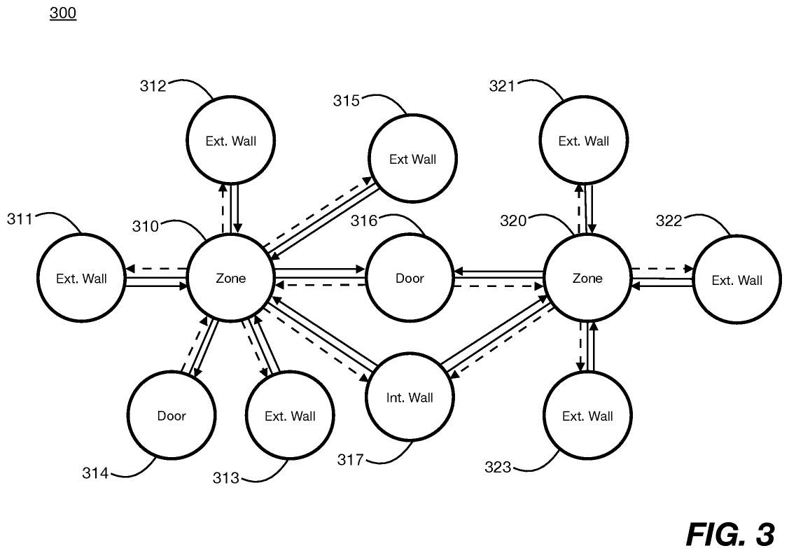

The digital twin application device 200 includes a digital twin 210, which may be stored in a database 212. The digital twin 210 may correspond to the digital twin 120 or a portion thereof (e.g., those portions relevant to the applications provided by the digital twin application device 200). The digital twin 210 may be used to drive or otherwise inform many of the applications provided by the digital twin application device 200. A digital twin 210 may be any data structure that models a real-life object, device, system, or other entity. Examples of a digital twin 210 useful for various embodiments will be described in greater detail below with reference to FIG. 3. While various embodiments will be described with reference to a particular set of heterogeneous and omnidirectional neural network digital twins, it will be apparent that the various techniques and embodiments described herein may be adapted to other types of digital twins. In some embodiments, additional systems, entities, devices, processes, or objects may be modeled and included as part of the digital twin 210.

In some embodiments, the digital twin 210 may be created and used entirely locally to the digital twin application device 200. In others, the digital twin 210 may be made available to or from other devices via a communication interface 220. The communication interface 220 may include virtually any hardware for enabling connections with other devices, such as an Ethernet network interface card (NIC), WiFi NIC, Bluetooth interface, or USB interface.

A digital twin sync process 222 may communicate with one or more other devices via the communication interface 220 to maintain the state of the digital twin 210. For example, where the digital twin application device 200 creates or modifies the digital twin 210 to be used by other devices, the digital twin sync process 222 may send the digital twin 210 or updates thereto to such other devices as the user changes the digital twin 210. Similarly, where the digital twin application device 200 uses a digital twin 210 created or modified by another device, the digital twin sync process 222 may request or otherwise receive the digital twin 210 or updates thereto from the other devices via the communication interface 220, and commit such received data to the database 212 for use by the other components of the digital twin application device 200. In some embodiments, both of these scenarios simultaneously exist as multiple devices collaborate on creating, modifying, and using the digital twin 210 across various applications. As such, the digital twin sync process 222 (and similar processes running on such other devices) may be responsible for ensuring that each device participating in such collaboration maintains a current copy of the digital twin, as presently modified by all other such devices. In various embodiments, this synchronization is accomplished via a pub/sub approach, wherein the digital twin sync process 222 subscribes to updates to the digital twin 210 and publishes its own updates to be received by similarly-subscribed devices. Such a pub/sub approach may be supported by a centralized process, such as a process running on a central server or central cloud instance.

To enable user interaction with the digital twin 210, the digital twin application device 200 includes a user interface 230. For example, the user interface 230 may include a display, a touchscreen, a keyboard, a mouse, or any device capable of performing input or output functions for a user. In some embodiments, the user interface 230 may instead or additionally allow a user to use another device for such input or output functions, such as connecting a separate tablet, mobile phone, or other device for interacting with the digital twin application device 200. In some embodiments, the user interface 230 includes a web server that serves interfaces to a remote user's personal device (e.g., via the communications interface). Thus, in some embodiments, the applications provided by the digital twin application device 200 may be provided as a web-based software-as-a-service (SaaS) offering.

The user interface 230 may rely on multiple additional components for constructing one or more graphical user interfaces for interacting with the digital twin 210. A scene manager 232 may store definitions of the various interface scenes that may be offered to the user. As used herein, an interface scene will be understood to encompass a collection of panels, tools, and other GUI elements for providing a user with a particular application (or set of applications). For example, four interface scenes may be defined, respectively for a building design application, a site analysis application, a simulation application, and a live building analysis application. It will be understood that various customizations and alternate views may be provided to a particular interface scene without constituting an entirely new interface scene. For example, panels may be rearranged, tools may be swapped in and out, and information displayed may change during operation without fundamentally changing the overall application provided to the user via that interface scene.

The UI tool library 234 stores definitions of the various tools that may be made available to the user via the user interface 230 and the various interface scenes (e.g., by way of a selectable interface button). These tool definitions in the UI tool library 234 may include software defining manners of interaction that add to, remove from, or modify aspects of the digital twin. As such, tools may include a user-facing component that enables interaction with aspects of the user interface scene, and a digital twin-facing component that captures the context of the user's interactions, and instructs the digital twin modifier 252 or generative engine 254 to make appropriate modifications to the digital twin 210. For example, a tool may be included in the UI tool library 234 that enables the user to create a zone. On the UI side, the tool enables the user to draw a square (or other shape) representing a new zone in a UI workspace. The tool then captures the dimensions of the zone and its position relative to the existing architecture, and passes this context to the digital twin modifier 252, so that a new zone can be added to the digital twin 210 with the appropriate position and dimensions.

A component library 236 stores definitions of various digital objects that may be made available to the user via the user interface 230 and the various interface scenes (e.g., by way of a selection of objects to drag-and-drop into a workspace). These digital objects may represent various real-world items such as devices (e.g., sensors, lighting, ventilation, user inputs, user indicators), landscaping, and other elements. The digital objects may include two different aspects: an avatar that will be used to graphically represent the digital object in the interface scene and an underlying digital twin that describes the digital object at an ontological or functional level. When the user indicates that a digital twin should be added to the workspace, the component library provides that object's digital twin to the digital twin modifier 252 so that it may be added to the digital twin 210.

A view manager 238 provides the user with controls for changing the view of the building rendering. For example, the view manager 238 may provide one or more interface controls to the user via the user interface to rotate, pan, or zoom the view of a rendered building; toggle between 2D and 3D renderings; or change which portions (e.g., floors) of the building are shown. In some embodiments, the view manager may also provide a selection of canned views from which the user may choose to automatically set the view to a particular state. The user's interactions with these controls are captured by the view manager 238 and passed on to the renderers 240, to inform the operation thereof.

The renderers 240 include a collection of libraries for generating the object representations that will be displayed via the user interface 230. In particular, where a current interface scene is specified by the scene manager 232 as including the output of a particular renderer 240, the user interface 230 may activate or otherwise retrieve image data from that renderer for display at the appropriate location on the screen.

Some renderers 240 may render the digital twin (or a portion thereof) in visual form. For example, the building renderer 242 may translate the digital twin 210 into a visual depiction of one or more floors of the building it represents. The manner in which this is performed may be driven by the user via settings passed to the building renderer via the view manager. For example, depending on the user input, the building renderer may generate a 2D plan view of floors 2, 3, and 4; a 3D isometric view of floor 1 from the southwest corner; or a rendering of the exterior of the entire building.

Some renderers 240 may maintain their own data for rendering visualizations. For example, in some embodiments, the digital twin 210 may not store sufficient information to drive a rendering of the site of a building. For example, rather than storing map, terrain, and architectures of surrounding buildings in the digital twin 210, the site renderer 244 may obtain this information based on the specified location for the building. In such embodiments, the site renderer may obtain this information via the communication interface 220, generate intermediate description of the surrounding environment (e.g., descriptions of the shapes of other buildings in the vicinity of the subject building), and store this for later user (e.g., in the database 212, separate from the digital twin). Then, when the user interface 230 calls on the site renderer 244 to provide a site rendering, the site renderer 244 uses this intermediate information along with the view preferences provided by the view manager, to render a visualization of the site and surrounding context. In other embodiments where the digital twin 210 does store sufficient information for rendering the site (or where other digital twins are available to the digital twin application device 200 with such information), the site renderer 244 may render the site visualization based on the digital twin in a manner similar to the building renderer 240.

Some renderers 240 may produce visualizations based on information stored in the digital twin (as opposed to rendering the digital twin itself). For example, the digital twin 210 may store a temperature value associated with each zone. The overlay renderer 246 may produce an overlay that displays the relevant temperature value over each zone rendered by the building renderer 242. Similarly, some renderers 240 may produce visualizations based on information provided by other components. For example, an application tool 260 may produce an interpolated gradient of temperature values across the zones and the overlay renderer 246 may produce an overlay with a corresponding color-based gradient across the floors of each zone rendered by the building renderer 242.

As noted above, while various tools in the UI tool library 234 provide a user experience of interacting directly with the various renderings shown in the interface scene, these tools actually provide a means to manipulate the digital twin 210. These changes are then picked up by the renderers 240 for display. To enable these changes to the digital twin, a digital twin modifier 252 provides a library for use by the UI tool library 234, user interface 230, component library 236 or other components of the digital twin application device 200. The digital twin modifier 252 may be capable of various modifications such as adding new nodes to the digital twin; removing nodes from the digital twin; modifying properties of nodes; adding, changing, or removing connections between nodes; or adding, modifying, or removing sets of nodes (e.g., as may be corelated to a digital object in the component library 236). In many instances, the user instructs the digital twin modifier 252 what changes to make to the digital twin 210 (via the user interface 230, UI tool library 234, or other component). For example, a tool for adding a zone, when used by the user, directly instructs the digital twin modifier to add a zone node and wall nodes surrounding it to the digital twin. As another example, where the user interface 230 provides a slider element for modifying an R-value of a wall, the user interface 230 will directly instruct the digital twin to find the node associated with the selected wall and change the R-value thereof.

In some cases, one or more contextual, constraint-based, or otherwise intelligent decisions are to be made in response to user input to determine how to modify the digital twin 210. These more complex modifications to the digital twin 210 may be handled by the generative engine 254. For example, when a new zone is drawn, the walls surrounding it may have difference characteristics depending on whether they should be interior or exterior walls. This decision, in turn, is informed by the context of the new zone in relation to other zones and walls. If the wall will be adjacent another zone, it should be interior; if not, it should be exterior. In this case, the generative engine 254 may be configured to recognize specific contexts and interpret them according to, e.g., a rule set to product the appropriate modifications to the digital twin 210.

As another example, in some embodiments, a tool may be provided to the user for generating structure or other object based on some constraint or other setting. For example, rather than using default or typical roof construction, the user may specify that the roof should be dome shaped. Then, when adding a zone to the digital twin, the generative engine may generate appropriate wall constructions and geometries, and any other needed supports, to provide a structurally-sound building. To provide this advanced functionality, the generative engine 254 may include libraries implementing various generative artificial intelligence techniques. For example, the generative engine 254 may add new nodes to the digital twin, create a cost function representing the desired constraints and certain tunable parameters relevant to fulfilling those constraints, and perform gradient descent to tune the parameters of the new nodes to provide a constraint (or other preference) solving solution.

Various interface scenes may provide access to additional application tools 260 beyond means for modifying the digital twin and displaying the results. As shown, some possible application tools include one or more analytics tools or simulators 264. The analytics tools 262 may provide advanced visualizations for showing the information captured in the digital twin 262. As in an earlier mentioned example, an analytics tool 262 may interpolate temperatures across the entire footprint of a floorplan, so as to enable the overlay renderer 246 to provide an enhanced view of the temperature of the building compared to the point temperatures that may be stored in each node of the digital twin 210. In some embodiments, these analytics and associated overlay may be updated in real time. To realize such functionality, a separate building controller (not shown) may continually or periodically gather temperature data from various sensors deployed in the building. These updates to that building controller's digital twin may then be synchronized to the digital twin 210 (through operation of the digital twin sync process 222), which then drives updates to the analytics tool.

As another example, an analytics tool 262 may extract entity or object locations from the digital twin 210, so that the overlay renderer 246 can then render a live view of the movement of those entities or objects through the building. For example, where the building is a warehouse, inventory items may be provided with RFID tags and an RFID tracking system may continually update its version of the building digital twin with inventory locations. Then, as this digital twin is continually or periodically synced to the local digital twin 210, the object tracking analytics tool 262 may extract this information from the digital twin 262 to be rendered. In this way, the digital twin application device 200 may realize aspects of a live, operational BIM.

The application tools 260 may also include one or more simulators 264. As opposed to the analytics tools 262 which focus on providing informative visualizations of the building as it is, the simulator tools 264 may focus on predicting future states of the building or predicting current states of the building that are not otherwise captured in the digital twin 210. For example, a shadow simulator 264 may use the object models used by the site renderer to simulate shadows and sub exposure on the building rendering. This simulation information may be provided to the renderers 240 for rendering visualizations of this shadow coverage. As another example, an operation simulator 264 may simulate operations of the digital twin 210 into the future and provide information for the user interface 230 to display graphs of the simulated information. As one example, the operation simulator 264 may simulate the temperature of each zone of the digital twin 210 for 7 days into the future. The associated interface scene may then drive the user interface to construct and display a line graph from this data so that the user can view and interact with the results. Various additional application tools 260, methods for integrating their results into the user interface 230, and methods for enabling them to interact with the digital twin 210 will be apparent.

FIG. 3 illustrates an example digital twin 300 for construction by or use in various embodiments. The digital twin 300 may correspond, for example, to digital twin 120 or digital twin 210. As shown, the digital twin 300 includes a number of nodes 310, 311, 312, 313, 314, 315, 316, 320, 321, 322, 323 connected to each other via edges. As such, the digital twin 300 may be arranged as a graph, such as a neural network. In various alternative embodiments, other arrangements may be used. Further, while the digital twin 300 may reside in storage as a graph type data structure, it will be understood that various alternative data structures may be used for the storage of a digital twin 300 as described herein. The nodes 310-323 may correspond to various aspects of a building structure such as zones, walls, and doors. The edges between the nodes 310-323 may, then, represent relationships between the aspects represented by the nodes 310-323 such as, for example, adjacency for the purposes of heat transfer.

As shown, the digital twin 300 includes two nodes 310, 320 representing zones. A first zone node 310 is connected to four exterior wall nodes 311, 312, 313, 315; two door nodes 314, 316; and an interior wall node 317. A second zone node 320 is connected to three exterior wall nodes 321, 322, 323; a door node 316; and an interior wall node 317. The interior wall node 317 and door node 316 are connected to both zone nodes 310, 320, indicating that the corresponding structures divide the two zones. This digital twin 300 may thus correspond to a two-room structure, such as the one depicted by the building rendering 152 of FIG. 1.

It will be apparent that the example digital twin 300 may be, in some respects, a simplification. For example, the digital twin 300 may include additional nodes representing other aspects such as additional zones, windows, ceilings, foundations, roofs, or external forces such as the weather or a forecast thereof. It will also be apparent that in various embodiments the digital twin 300 may encompass alternative or additional systems such as controllable systems of equipment (e.g., HVAC systems).

According to various embodiments, the digital twin 300 is a heterogenous neural network. Typical neural networks are formed of multiple layers of neurons interconnected to each other, each starting with the same activation function. Through training, each neuron's activation function is weighted with learned coefficients such that, in concert, the neurons cooperate to perform a function. The example digital twin 300, on the other hand, may include a set of activation functions (shown as solid arrows) that are, even before any training or learning, differentiated from each other, i.e., heterogenous. In various embodiments, the activation functions may be assigned to the nodes 310-323 based on domain knowledge related to the system being modeled. For example, the activation functions may include appropriate heat transfer functions for simulating the propagation of heat through a physical environment (such as function describing the radiation of heat from or through a wall of particular material and dimensions to a zone of particular dimensions). As another example, activation functions may include functions for modeling the operation of an HVAC system at a mathematical level (e.g., modeling the flow of fluid through a hydronic heating system and the fluid's gathering and subsequent dissipation of heat energy). Such functions may be referred to as “behaviors” assigned to the nodes 310-323. In some embodiments, each of the activation functions may in fact include multiple separate functions; such an implementation may be useful when more than one aspect of a system may be modeled from node-to-node. For example, each of the activation functions may include a first activation function for modeling heat propagation and a second activation function for modeling humidity propagation. In some embodiments, these diverse activation functions along a single edge may be defined in opposite directions. For example, a heat propagation function may be defined from node 310 to node 311, while a humidity propagation function may be defined from node 311 to node 310. In some embodiments, the diversity of activation functions may differ from edge to edge. For example, one activation function may include only a heat propagation function, another activation function may include only a humidity propagation function, and yet another activation function may include both a heat propagation function and a humidity propagation function.

According to various embodiments, the digital twin 300 is an omnidirectional neural network. Typical neural networks are unidirectional-they include an input layer of neurons that activate one or more hidden layers of neurons, which then activate an output layer of neurons. In use, typical neural networks use a feed-forward algorithm where information only flows from input to output, and not in any other direction. Even in deep neural networks, where other paths including cycles may be used (as in a recurrent neural network), the paths through the neural network are defined and limited. The example digital twin 300, on the other hand, may include activation functions along both directions of each edge: the previously discussed “forward” activation functions (shown as solid arrows) as well as a set of “backward” activation functions (shown as dashed arrows).

In some embodiments, at least some of the backward activation functions may be defined in the same way as described for the forward activation functions-based on domain knowledge. For example, while physics-based functions can be used to model heat transfer from a surface (e.g., a wall) to a fluid volume (e.g., an HVAC zone), similar physics-based functions may be used to model heat transfer from the fluid volume to the surface. In some embodiments, some or all of the backward activation functions are derived using automatic differentiation techniques. Specifically, according to some embodiments, reverse mode automatic differentiation is used to compute the partial derivative of a forward activation function in the reverse direction. This partial derivative may then be used to traverse the graph in the opposite direction of that forward activation function. Thus, for example, while the forward activation function from node 311 to node 310 may be defined based on domain knowledge and allow traversal (e.g., state propagation as part of a simulation) from node 311 to node 310 in linear space, the reverse activation function may be defined as a partial derivative computed from that forward activation function and may allow traversal from node 310 to 311 in the derivative space. In this manner, traversal from any one node to any other node is enabled—for example, the graph may be traversed (e.g. state may be propagated) from node 312 to node 313, first through a forward activation function, through node 310, then through a backward activation function. By forming the digital twin as an omnidirectional neural network, its utility is greatly expanded; rather than being tuned for one particular task, it can be traversed in any direction to simulate different system behaviors of interest and may be “asked” many different questions.

According to various embodiments, the digital twin is an ontologically labeled neural network. In typical neural networks, individual neurons do not represent anything in particular; they simply form the mathematical sequence of functions that will be used (after training) to answer a particular question. Further, while in deep neural networks, neurons are grouped together to provide higher functionality (e.g. recurrent neural networks and convolutional neural networks), these groupings do not represent anything other than the specific functions they perform; i.e., they remain simply a sequence of operations to be performed.

The example digital twin 300, on the other hand, may ascribe meaning to each of the nodes 310-323 and edges therebetween by way of an ontology. For example, the ontology may define each of the concepts relevant to a particular system being modeled by the digital twin 300 such that each node or connection can be labeled according to its meaning, purpose, or role in the system. In some embodiments, the ontology may be specific to the application (e.g., including specific entries for each of the various HVAC equipment, sensors, and building structures to be modeled), while in others, the ontology may be generalized in some respects. For example, rather than defining specific equipment, the ontology may define generalized “actors” (e.g., the ontology may define producer, consumer, transformer, and other actors for ascribing to nodes) that operate on “quanta” (e.g., the ontology may define fluid, thermal, mechanical, and other quanta for propagation through the model) passing through the system. Additional aspects of the ontology may allow for definition of behaviors and properties for the actors and quanta that serve to account for the relevant specifics of the object or entity being modeled. For example, through the assignment of behaviors and properties, the functional difference between one “transport” actor and another “transport” actor can be captured.

The above techniques, alone or in combination, may enable a fully-featured and robust digital twin 300, suitable for many purposes including system simulation and control path finding. The digital twin 300 may be computable and trainable like a neural network, queryable like a database, introspectable like a semantic graph, and callable like an API.

As described above, the digital twin 300 may be traversed in any direction by application of activation functions along each edge. Thus, just like a typical feedforward neural network, information can be propagated from input node(s) to output node(s). The difference is that the input and output nodes may be specifically selected on the digital twin 300 based on the question being asked, and may differ from question to question. In some embodiments, the computation may occur iteratively over a sequence of timesteps to simulate over a period of time. For example, the digital twin 300 and activation functions may be set at a particular timestep (e.g., 1 minute), such that each propagation of state simulates the changes that occur over that period of time. Thus, to simulate longer period of time or point in time further in the future (e.g., one minute), the same computation may be performed until a number of timesteps equaling the period of time have been simulated (e.g., 60 one second time steps to simulate a full minute). The relevant state over time may be captured after each iteration to produce a value curve (e.g., the predicted temperature curve at node 310 over the course of a minute) or a single value may be read after the iteration is complete (e.g., the predicted temperature at node 310 after a minute has passed). The digital twin 300 may also be inferenceable by, for example, attaching additional nodes at particular locations such that they obtain information during computation that can then be read as output (or as an intermediate value as described below).

While the forward activation functions may be initially set based on domain knowledge, in some embodiments training data along with a training algorithm may be used to further tune the forward activation functions or the backward activation functions to better model the real world systems represented (e.g., to account for unanticipated deviations from the plans such as gaps in venting or variance in equipment efficiency) or adapt to changes in the real world system over time (e.g., to account for equipment degradation, replacement of equipment, remodeling, opening a window, etc.).

Training may occur before active deployment of the digital twin 300 (e.g., in a lab setting based on a generic training data set) or as a learning process when the digital twin 300 has been deployed for the system it will model. To create training data for active-deployment learning, a controller device (not shown) may observe the data made available from the real-world system being modeled (e.g., as may be provided by a sensor system deployed in the environment 110) and log this information as a ground truth for use in training examples. To train the digital twin 300, that controller may use any of various optimization or supervised learning techniques, such as a gradient descent algorithm that tunes coefficients associated with the forward activation functions or the backward activation functions. The training may occur from time to time, on a scheduled basis, after gathering of a set of new training data of a particular size, in response to determining that one or more nodes or the entire system is not performing adequately (e.g., an error associated with one or more nodes 310-323 passed a threshold or passes that threshold for a particular duration of time), in response to manual request from a user, or based on any other trigger. In this way, the digital twin 300 may be adapted to better adapt its operation to the real world operation of the systems it models, both initially and over the lifetime of its deployment, by tacking itself to the observed operation of those systems.

The digital twin 300 may be introspectable. That is, the state, behaviors, and properties of the 310-323 may be read by another program or a user. This functionality is facilitated by association of each node 310-323 to an aspect of the system being modeled. Unlike typical neural networks where, due to the fact that neurons don't represent anything particularly the internal values are largely meaningless (or perhaps exceedingly difficult or impossible to ascribe human meaning), the internal values of the nodes 310-323 can easily be interpreted. If an internal “temperature” property is read from node 310, it can be interpreted as the anticipated temperature of the system aspect associated with that node 310.

Through attachment of a semantic ontology, as described above, the introspectability can be extended to make the digital twin 300 queryable. That is, ontology can be used as a query language usable to specify what information is desired to be read from the digital twin 300. For example, a query may be constructed to “read all temperatures from zones having a volume larger than 200 square feet and an occupancy of at least 1.” A process for querying the digital twin 300 may then be able to locate all nodes 310-323 representing zones that have properties matching the volume and occupancy criteria, and then read out the temperature properties of each. The digital twin 300 may then additionally be callable like an API through such processes. With the ability to query and inference, canned transactions can be generated and made available to other processes that aren't designed to be familiar with the inner workings of the digital twin 300. For example, an “average zone temperature” API function could be defined and made available for other elements of the controller or even external devices to make use of. In some embodiments, further transformation of the data could be baked into such canned functions. For example, in some embodiments, the digital twin 300 itself may not itself keep track of a “comfort” value, which may defined using various approaches such as the Fanger thermal comfort model. Instead, e.g., a “zone comfort” API function may be defined that extracts the relevant properties (such as temperature and humidity) from a specified zone node, computes the comfort according to the desired equation, and provides the response to the calling process or entity.

It will be appreciated that the digital twin 300 is merely an example of a possible embodiment and that many variations may be employed. In some embodiments, the number and arrangements of the nodes 310-323 and edges therebetween may be different, either based on the device implementation or based on the system being modeled. For example, a controller deployed in one building may have a digital twin 300 organized one way to reflect that building and its systems while a controller deployed in a different building may have a digital twin 300 organized in an entirely different way because the building and its systems are different from the first building and therefore dictate a different model. Further, various embodiments of the techniques described herein may use alternative types of digital twins. For example, in some embodiments, the digital twin 300 may not be organized as a neural network and may, instead, be arranged as another type of model for one or more components of the environment 110. In some such embodiments, the digital twin 300 may be a database or other data structure that simply stores descriptions of the system aspects, environmental features, or devices being modeled, such that other software has access to data representative of the real world objects and entities, or their respective arrangements, as the software performs its functions.

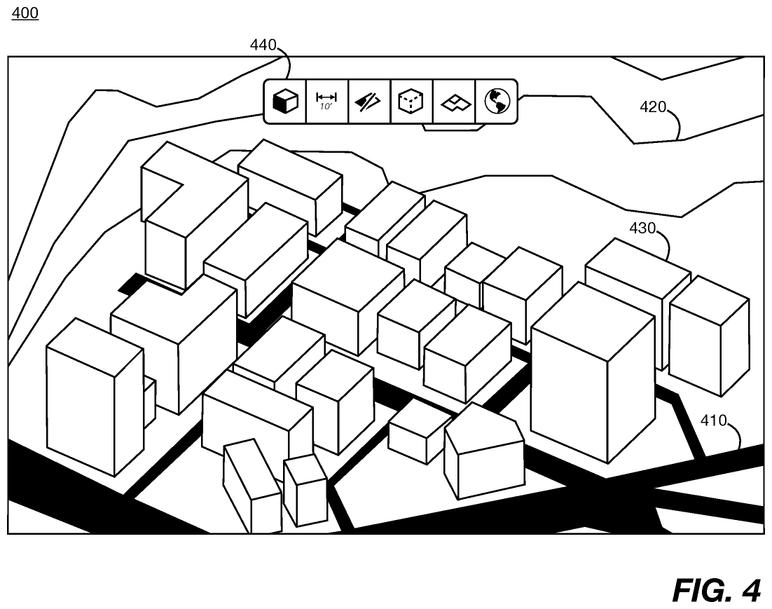

FIG. 4 illustrates an example graphical user interface 400 for visualizing a site. This GUI 400 may be created as (or as part of) an interface scene associated with a site planning application offered by the digital twin application device 200. As such, various elements may be rendered or displayed by the user interface 230, UI tool library 234, or renderers 240 as may be directed by the scene manager 232. Further, the GUI 400 (and other GUIs presented herein) may be displayed along with other panes, panels, or UI elements not shown (e.g., as a single panel in a multi-panel interface). This GUI 400 may be displayed for a particular location such as a location previously associated with a building's digital twin or a location selected by the user on a preceding GUI (not shown) that presents an interactive map for such purpose. As shown, the rendering includes a road map rendering 410, terrain rendering 420, and surrounding building renderings 430.

The road map rendering 410 may include graphical, satellite, or other representations of road in the area being displayed. This information may be obtained from various sources such as an open map or satellite data database accessible via an API. Further, road map rendering 410 may include additional or alternative information from the roads displayed. For example, the road map rendering 410 may include representations of rivers, trees, and other natural features; or the tops of various buildings and other structures, as may be gathered by satellite imaging. To begin the rendering process, the obtained road map data may be applied as a texture to a plane or 3D mesh object initially in a planar configuration.

The terrain rendering 420 may convey elevation or other terrain data, which may be obtained from various sources such as an open elevation database accessible via an API. This data may then be used to deform the plane to which the map data was applied as a texture, thereby modifying the displayed map to appear, in a 3D view, to follow the terrain contours of the real site being recreated.

The surrounding building renderings 430 may convey information about the geometry of the structures at the site. Various methods may be used to identify building geometries from available data such as image recognition methods to identify rooftops or elevations from satellite data; obtaining available elevation data from an external source; or obtaining information from other digital twins created for some or all of the other buildings (e.g., by querying respective controllers installed in or otherwise associated with those buildings). Once the surrounding building shapes are identified, various approaches may be employed to place these surrounding building renderings 430 in the GUI 400 such as, for example, rendering discrete objects in the shape of the buildings or in the shape of primitives (e.g., simple boxes); or by extruding the ground plane in the location of the surrounding buildings 430 upward to the presumed height of each building. Similar approaches may be used to account for other surrounding 3D geometry such as trees and other landscaping, structures such as bridges, or anything else that may be useful for the purposes of the application associated with the GUI 400.

The GUI 400 also includes a collection of buttons 440 associated with UI tools, linked to other interface scenes, or that otherwise provide the user with the to interact with the renderings 410, 420, 430 or other aspects of the GUI 400. Example tools to make available are a button for accessing a tool for performing measurements of the rendered environment; a button for adding or removing geometry from one or more of the renderings or aspects thereof 410, 420, 430; a button for returning to an interface scene providing location picker map; or a button to initiate placement (or re-placement) of a building in the environment using an autosmasher as described herein. Various additional interface elements (not shown) may also be provided for other interactions, such as changing (panning, zooming, rotating) the view of the renderings 410, 420, 430 or for initiating other functionality such as a shadow/sun exposure simulation.

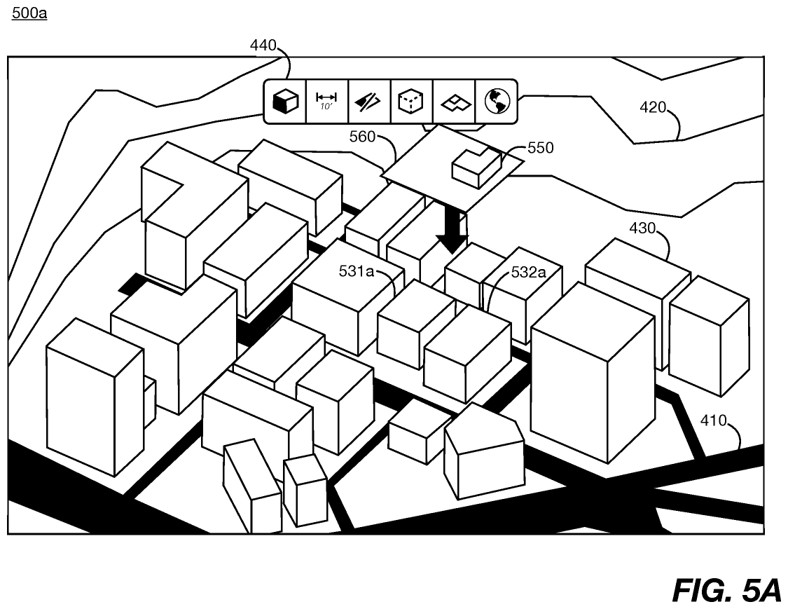

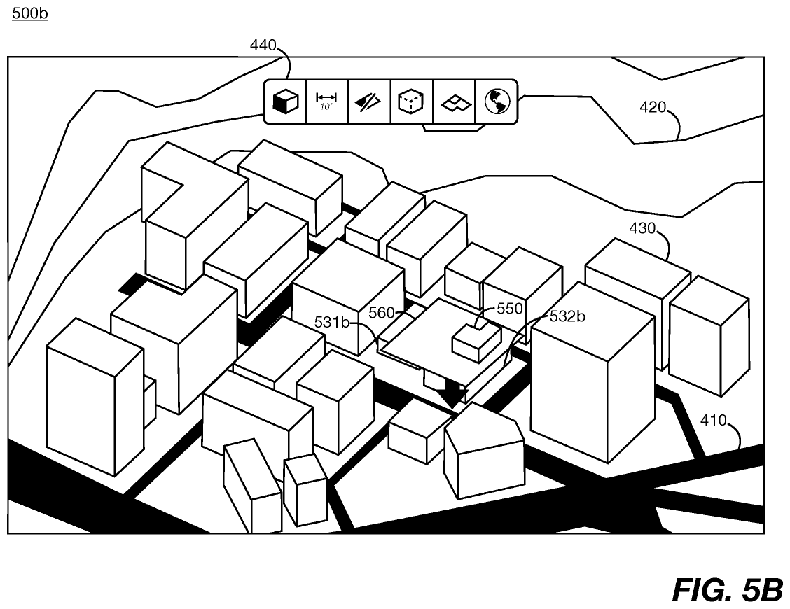

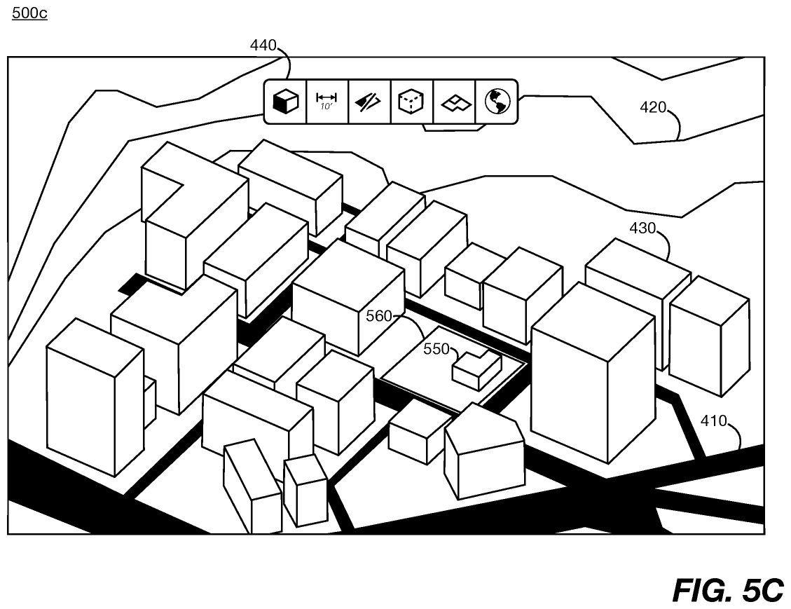

FIG. 5A illustrates a first example graphical user interface 500a for visualizing an autosmasher. This GUI 500a may be created as (or as part of) an interface scene associated with a site planning application offered by the digital twin application device 200. As such, various elements may be rendered or displayed by the user interface 230, UI tool library 234, or renderers 240 as may be directed by the scene manage 232. As shown, the GUI 500a includes various elements 410, 420, 430, 440 previously described with respect to the GUI 400 and, as such, GUI 500a may be displayed in response to a user interaction with GUI 400 such as, for example, an indication to access the autosmasher or otherwise to place a building in the context of the rendered environment 410, 420, 430.

In addition to the previously-rendered items, the GUI 500a adds a subject building 550 together with an autosmasher footprint 560. The subject building 550 may be one or more buildings that the user has indicated a desire to view in the context of the rendered site 410-430. For example, the subject building 550 may be a building created or modified by the user using an interface scene associated with a building design application, as previously described, or may be a building associated with a digital twin obtained from another device (e.g., via the digital twin sync process 222) and selected by the user for display. As previously described, the subject building may be rendered (e.g., by the building renderer 242) from a digital twin or portion thereof.

The autosmasher footprint 560 is displayed here as a plane, though other elements for communicating the shape of the area that will be leveled, destroyed, or otherwise prepared for placement of the subject building 550 may be used. The shape and scale of the autosmasher footprint 560 may also be determined in various manners. In some embodiments, the autosmasher footprint 560 dimensions are defined in a digital twin, metadata associated with the project, manually set by the user, or otherwise made available a priori. In some embodiments, the autosmasher footprint 560 is automatically generated at or near the time of rendering the GUI 500a. According to one approach, the autosmasher footprint 560 is identical to the footprint of the subject building 550, or is the footprint of the subject building 500 that has been expanded outward by some distance (e.g., by 20 feet in each direction based on a default setting or based on a setting provided by the digital twin, project metadata, user, etc.). In some embodiments, the autosmasher footprint 560 is a regular shape (e.g., a square) of a size that is deemed appropriate to the size of the subject building 550.

In some embodiments, the autosmasher footprint 560 dimensions are at least partially determined by the environment geometry 410-430. For example, the natural lot boundaries created by the roads in the map rendering 410 (or underlying map data) may be used to shape the perimeter of the autosmasher footprint 560 so that it will fit naturally in the space below. In a similar manner, the legal recorded definitions of lot boundaries may be used to shape the autosmasher footprint 560 such that it will fit to one or more such boundaries. Other contextual data may also be used to size and shape the autosmasher footprint 560 such as geographical features (e.g., bodies of water and extreme topology changes) or existing structures (e.g., reshaping the autosmasher footprint 560 so as to avoid demolishing certain structures or any structures).

The GUI 500a displays the subject building 550 and autosmasher footprint 560 as visually “hovering” over the other renderings 410, 420, 430. In particular, the subject building 550 and autosmasher footprint 560 are displayed directly above two of the rendered surrounding buildings 531a, 532a. This fact may be visually-indicated to the user by, e.g., highlighting the buildings 531a, 532a so that they appear distinguishable from other surrounding buildings 430. Such highlighting indicates to the user that these buildings 531a, 532a will be demolished by the autosmasher to make room for the hovering elements 550, 560. Identification of these buildings may be accomplished by casting one or more rays directly downward from one or more points on the autosmasher footprint 560 and identifying any objects intersected before reaching the ground plane (e.g., the map rendering 410 as deformed by the terrain rendering 420). Thus, any objects that are entirely underneath the autosmasher footprint 560 (such as building 532a) or only partially underneath the autosmasher footprint 560 (such as building 531a) may be identified for demolition.

In some embodiments, the user may be able to adjust the location of the subject building 550 and autosmasher footprint 560 before autosmashing is performed by, for example, clicking and dragging the hovering elements 550, 560 to other locations. As the hovering elements 550, 560 move, positional aspects of the GUI 500a may update as well such as the portion of the surrounding environment 410, 420, 430 that is rendered (e.g., panning to show other surroundings that were previously off-screen); the shape of the autosmasher footprint 560 (e.g., to continually adapt to the shape to the city blocks lying underneath); or the highlight of the surrounding buildings 430, 531a, 532a (to continue to accurately indicate which buildings currently underly the hovering elements 550, 560). Once the user is satisfied with the location, the user may indicate that autosmashing should commence (e.g., by clicking a button or simply letting go of a current click-and-drag action).

FIG. 5B illustrates a second example graphical user interface 500b for visualizing an autosmasher. This GUI 500b may be displayed as part of an autosmashing animation, after the user has instructed the procedure to commence. In particular, GUI 500b may illustrate a single frame in a multi-frame animation of the subject building 550 and autosmasher footprint 560 virtually “falling” into the desired location in the rendered surroundings 410-430. As the now-falling elements 550, 560 contact the buildings 531b, 532b undernearth, these buildings may also be animated in some way to illustrate their demolition. The specific example of GUI 500b shows a single frame of a multi-frame animation wherein the buildings 531b, 532b are “smashed”, and are scaled downward in the vertical direction such that they continue to fit in the space between the ground plane 410,420 and the autosmasher footprint 560 as the autosmasher footprint 560 continues to move downward into place. Other methods for making these buildings 531b, 532b “disappear” from view will be apparent such as moving them downward through the ground plane 410,420 and out of view (i.e., rendered under the ground plane 410, 420 and therefore not visible to the user); deleting them from the group of surrounding objects 430 to be displayed; or playing a separate animation (e.g., such as an explosion animation) and removing them from the rendering thereafter.

FIG. 5C illustrates a third example graphical user interface 500c for visualizing an autosmasher. This GUI 500c may illustrate the state of the rendered environment 410-430, 550-560 after autosmashing has been completed and, as such, may follow GUIs 500a,b in sequence. The subject building 550 and autosmasher footprint 560 are in place and the previously-displayed buildings 531a, 532a are no longer visible. In some alternative embodiments, at least a portion of the buildings 531a, 532a may still be visible such as, for example, in a flattened rendering of those objects underneath the autosmasher footprint 560 or simply as rooftops in the map data used for the map rendering 410. From this view, the user may be able to continue their exploration of the site planning application by, for example, changing the view (e.g., pan, zoom, rotate), initating other applications (e.g., a shadow/light exposure simulation), or modifying the autosmasher (e.g., changing the location or changing the autosmasher footprint 560).

In addition to removal of surrounding buildings 430, the autosmasher may perform other functions for preparation of a virtual site for subject building 550 placement. As another example, the autosmasher may perform terrain leveling, such that the virtual site is sufficiently flat for subject building 550 placement. Various approaches may be employed for such terrain leveling. According to one approach, an average elevation is computed across the ground plane 410, 420 coincident with the autosmasher footprint 560. The ground plane 410, 420 in the footprint 560 region elevation is then set to this average elevation across the entire surface. Various additional improvements to this process may be employed as well such as setting the elevation of margin area near the perimeter of the autosmasher footprint 560 according to a gradient between the average elevation and the surrounding original elevation, so as to provide a more seamless transition between leveled and unleveled areas. As another example, rather than a pure average, an elevation may be optimized based on the relative costs between filling and excavating land. Other modifications will be apparent.

In various alternative embodiments, the hovering or falling animations may be replaced with other animations or omitted entirely. For example, in some embodiments, only GUI 500c may be displayed after the user selects a location or indicates a desire to use the autosmasher tool. Thus, the GUI 500c may be immediately rendered with no animations, and the site rendering 410-430, 550-560 may be shown already in “smashed” form. In such an embodiment, the user may be able to reposition the subject building 550 and autosmasher footprint 560 (e.g., by clicking and dragging) and may see similar immediate results of buildings 430 being autosmashed based on the new location.

According to various embodiments described herein, the process of autosmashing is performed in “one fell swoop.” That is, rather than having to utilize multiple tools to remove existing structures, level terrain, perform other site preparations, and place the building, the user simply identifies the location for placement and all of these functions are then performed automatically to place the building on a prepared site for visualization and simulation. In this manner, an improved method for enhanced user experience in virtual design and simulation environments is achieved. Additional technical benefits will be apparent in view of the techniques disclosed herein.

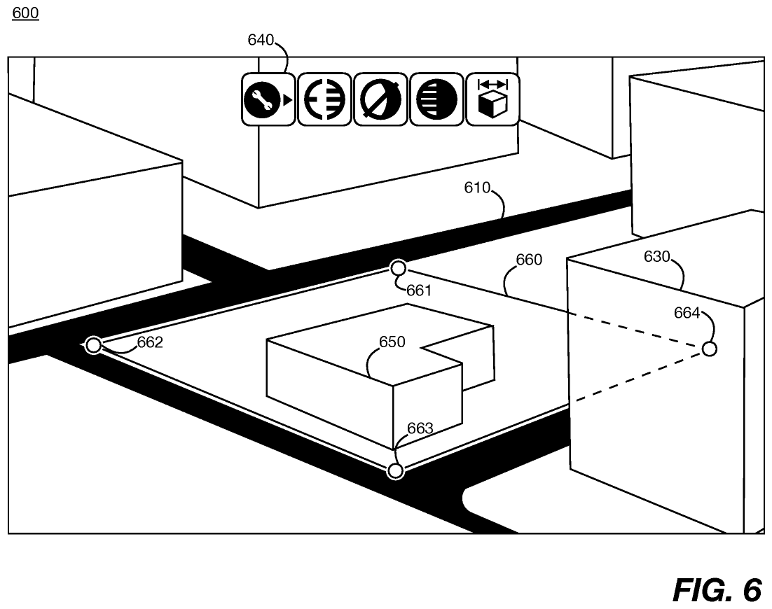

FIG. 6 illustrates an example graphical user interface 600 for modifying an autosmasher. This GUI 600 may be displayed after an autosmashing process has been complete to allow for further location refinement or other forms of interaction. For example, this GUI 600 may be displayed after GUI 500c has shown the post-autosmashing state of the virtual environment and after the user has zoomed in and rotated the view of the subject building 550 and autosmasher foorprint. The GUI 600 displays a map rendering 610 and multiple surrounding object renderings 630. These renderings 610, 630 may correspond to the renderings 410, 430, only viewed from a different camera position. Thus, while not shown, the virtual environment may also include a terrain rendering corresponding to the terrain rendering 420. The GUI 600 also includes multiple UI elements 640 for allowing the user to access different views and UI tools. For example, these UI elements 640 may include buttons for measuring distances in the rendered environment or for activating a shadow simulation tool. Various additional functions for the UI elements 640 will be apparent.

A subject building 650 is rendered, which may correspond to the subject building 550 or the designed building 152. Similarly an autosmasher footprint 660 is displayed, which may correspond to the autosmasher footprint 560 as previously described. According to various embodiments, the user may be able to reposition the subject building 650 within the autosmasher footprint 660. For example, the user may use various UI controls to click an drag the building to a new position relative to the autosmasher footprint 660, to rotate the building to face a different direction, or to change the elevation of the subject building 650 by raising or lowering the terrain elevation within the autosmasher footprint 660. Various other tools for altering the placement of the building 650 within the autosmasher footprint 660 and thus within the overall virtual environment will be apparent. Such movement of the subject building 650 relative to the autosmasher footprint 660 may be useful for various purposes such as judging aesthetics of the building placement or viewing simulation outcomes of various building placements. For example, where a shadow/sun exposure tool is available, the user may wish to test the sun exposure of the building 650 at various positions and orientations to select an ideal location. In some embodiments, such simulation output may be utilized to automatically optimize the placement of the building 650.

The GUI 600 may also provide various means for modifying the shape of the autosmasher footprint 660 and, consequently, the behavior of the autosmasher. As shown, the autosmasher footprint 660 includes four handles 661, 662, 663, 664 placed at each corner thereof. By clicking and dragging a handle 661, 662, 663, 664, the user may redefine the boundaries of the autosmasher footprint 660. For example, if the user clicked handle 664 and dragged it across the street, the autosmasher footprint 660 may then partially coincide with the building rendering 630 and, as such, the autosmasher may remove that building rendering 630 as well and perform other site preparation for the area within the new autosmasher footprint 660. In some embodiments, the GUI 600 may provide the user with the ability to add or delete handles 661-664, thereby modifying the shape by adding or deleting vertices to the polygon defining the autosmasher footprint 660 perimeter. In some embodiments, additional handles may be provided within the inner area of the autosmasher footprint 660 for modifying the shape by adjusting the elevation of the terrain. For example, a regular grid of such elevation handles may be disposed across the inner area of the autosmasher footprint 660. By modifying such elevation handles, the user may specify that the site should not be totally level (e.g., as described in the example of flattening the site to an average elevation) and, instead, should take on a particular topology. Consequently, the behavior of the autosmasher, rather than leveling the site to a planar autosmasher footprint 660, may be adapted to adapt the site to the contour of a non-planar autosmasher footprint 660.

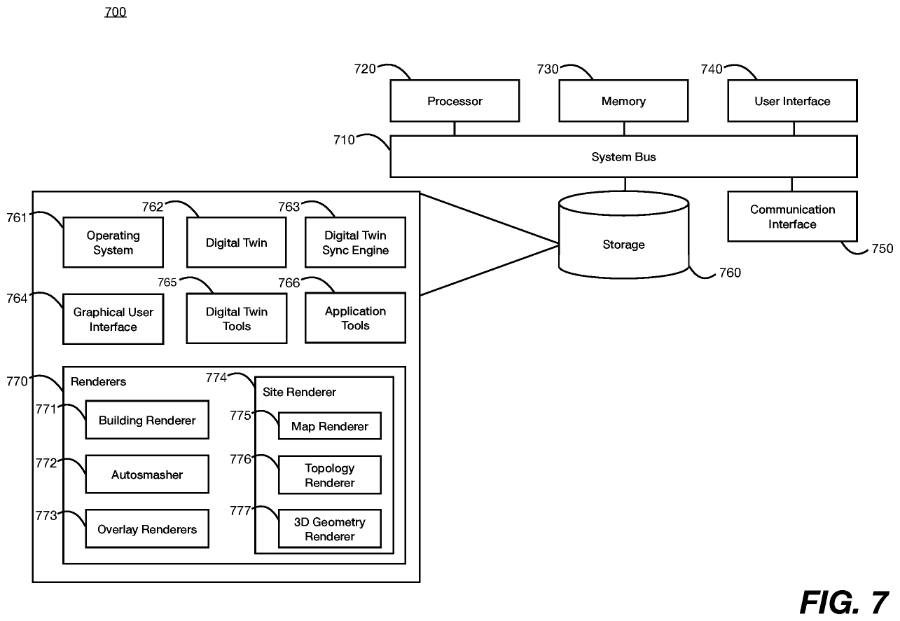

FIG. 7 illustrates an example hardware device 700 for implementing a digital twin application device. The hardware device 700 may describe the hardware architecture and some stored software of a device providing a digital twin application suite 130 or the digital twin application device 200. As shown, the device 700 includes a processor 720, memory 730, user interface 740, communication interface 750, and storage 760 interconnected via one or more system buses 710. It will be understood that FIG. 7 constitutes, in some respects, an abstraction and that the actual organization of the components of the device 700 may be more complex than illustrated.

The processor 720 may be any hardware device capable of executing instructions stored in memory 730 or storage 760 or otherwise processing data. As such, the processor 720 may include a microprocessor, field programmable gate array (FPGA), application-specific integrated circuit (ASIC), or other similar devices.

The memory 730 may include various memories such as, for example L1, L2, or L3 cache or system memory. As such, the memory 730 may include static random access memory (SRAM), dynamic RAM (DRAM), flash memory, read only memory (ROM), or other similar memory devices. It will be apparent that, in embodiments where the processor includes one or more ASICs (or other processing devices) that implement one or more of the functions described herein in hardware, the software described as corresponding to such functionality in other embodiments may be omitted.

The user interface 740 may include one or more devices for enabling communication with a user such as an administrator. For example, the user interface 740 may include a display, a mouse, a keyboard for receiving user commands, or a touchscreen. In some embodiments, the user interface 740 may include a command line interface or graphical user interface that may be presented to a remote terminal via the communication interface 750 (e.g., as a website served via a web server).

The communication interface 750 may include one or more devices for enabling communication with other hardware devices. For example, the communication interface 750 may include a network interface card (NIC) configured to communicate according to the Ethernet protocol. Additionally, the communication interface 750 may implement a TCP/IP stack for communication according to the TCP/IP protocols. Various alternative or additional hardware or configurations for the communication interface 750 will be apparent.

The storage 760 may include one or more machine-readable storage media such as read-only memory (ROM), random-access memory (RAM), magnetic disk storage media, optical storage media, flash-memory devices, or similar storage media. In various embodiments, the storage 760 may store instructions for execution by the processor 720 or data upon with the processor 720 may operate. For example, the storage 760 may store a base operating system 761 for controlling various basic operations of the hardware 700.

The storage 760 additionally includes a digital twin 762, such as a digital twin according to any of the embodiments described herein. As such, in various embodiments, the digital twin 762 includes a heterogeneous and omnidirectional neural network. A digital twin sync engine 763 may communicate with other devices via the communication interface 750 to maintain the local digital twin 762 in a synchronized state with digital twins maintained by such other devices. Graphical user interface instructions 764 may include instructions for rendering the various user interface elements for providing the user with access to various applications. As such, the GUI instructions 764 may correspond to one or more of the scene manager 232, UI tool library 234, component library 236, view manager 238, user interface 230, or portions thereof. Digital twin tools 765 may provide various functionality for modifying the digital twin 762 and, as such, may correspond to the digital twin modifier 252 or generative engine 254. Application tools 766 may include various libraries for performing functionality for interacting with the digital twin 762, such as computing advanced analytics from the digital twin 762 and performing simulations using the digital twin 762. As such, the application tools 766 may correspond to the application tools 260.

The storage 760 may also include a collection of renderers 770 for rendering various aspects of the digital twin 762, its intended environment, information computed by the application tools 766, or other information for display to the user via the user interface 740. As such, the renderers 770 may correspond to the renderers 240 and may be responsible for rendering 2D or 3D visualizations such as rendering 152 or the various renderings described with respect to FIGS. 4-6. Thus, the renderers 770 may include a building renderer 771 for rendering the digital twin 762 (or portions thereof) as a building and one or more overlay renderers for rendering information from the digital twin 762 or applications tools 766 as useful overlays. A site renderer 774 renders aspects of the surrounding environment and includes subcomponents such as, for example, a map renderer 775 for rendering a map as a starting point for a ground plane; a topology renderer 776 for rendering elevation data by, for example, deforming the ground plane according to the elevation data; and a 3D geometry renderer 777 for rendering other 3D objects such as buildings, trees, and the like. The renderers 770 also include autosmasher instructions 770 that modify the operation of the other renderers (e.g., the site renderer 774) to prepare a site in the virtual environment for placement of the building rendering.

While the hardware device 700 is shown as including one of each described component, the various components may be duplicated in various embodiments. For example, the processor 720 may include multiple microprocessors that are configured to independently execute the methods described herein or are configured to perform steps or subroutines of the methods described herein such that the multiple processors cooperate to achieve the functionality described herein, such as in the case where the device 700 participates in a distributed processing architecture with other devices which may be similar to device 700. Further, where the device 700 is implemented in a cloud computing system, the various hardware components may belong to separate physical systems. For example, the processor 720 may include a first processor in a first server and a second processor in a second server.

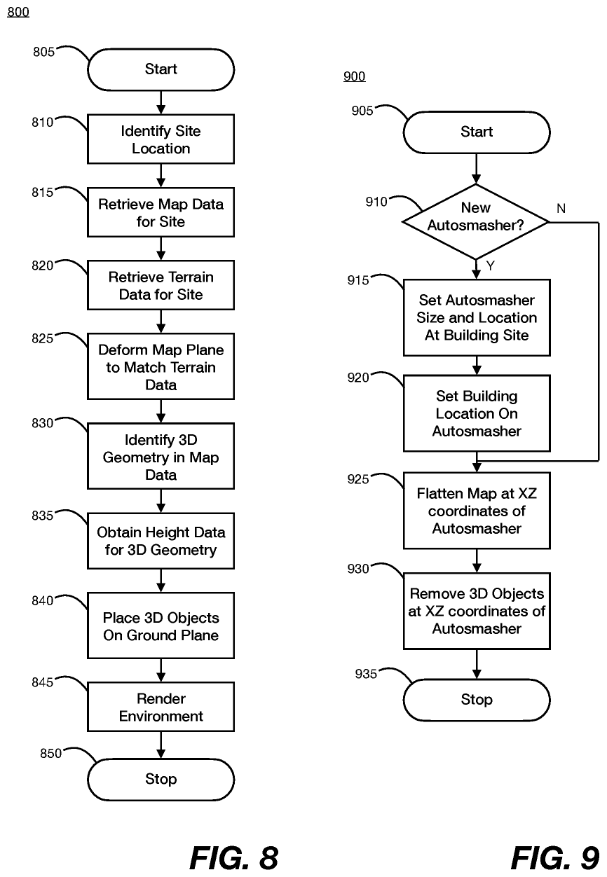

FIG. 8 illustrates an example method 800 for rendering an environment. The method 800 may correspond to the site renderer 244 or site renderer 774. The method 800 begins in step 805 in response to, for example, the user interface switching to an interface scene that calls for an environment rendering. The method 800 proceeds to step 810 where the device identifies the site location from, for example, metadata carried by the digital twin or manual specification by the user. The device then fetches map data and terrain/elevation data for that location in steps 815, 820 respectively. Various sources for obtaining such information will be apparent. In step 825, the method 800 begins creating the ground plane by applying the map data to a flat plane and then deforming the plane according to the terrain data.

Next, the device begins to render other surrounding objects, such as buildings and landscaping, by identifying any such 3D objects in the map data in step 830. Various approaches may be used to identify these 3D objects such as, for example, performing image recognition (e.g. to identify roofs in satellite data). In step 835, the device determines the heights for these 3D objects again by using any of various possible approaches. For example, another image recognition approach may be used to discern a height based on the length of shadows in the satellite data. It will be understood that other approaches may be utilized to know the locations, geometries and sizes of buildings and other 3D objects in the area. For example, steps 830, 835 may be replaced with a step that accesses 3D object data for the vicinity from a database or from other digital twins associated with other buildings in the area. For example, where such other buildings utilize digital-twin driven controllers or are associated with a building information model, the device may send a message (e.g., via an API) to such other devices requesting this data defining the size, shape, and location of the other buildings in the area.

Having identified one or more 3D objects for the environment in steps 830,835, the device then places these objects in the environment in step 840. According to some embodiments, each such object is placed as a new digital object in the environment to be rendered. The site renderer 774 may maintain this list of additional objects for rendering. In other embodiments, rather than creating additional discrete objects to be rendered, the ground plane is further deformed to account for the surrounding geometery. In particular, the ground plane may be extruded upward in the vicinity of each identified object to the height of the identified height. Various other approaches for placing these 3D objects in the scene for rendering will be apparent.

Finally, in step 845, the device renders the environment as set up in the previous steps. This rendering may be accomplished according to any known approach such as z-buffer rendering or ray-tracing. Such rendering may be from the point of view of a virtual camera, step owhose position, orientation, and other settings may be modifiable by the user. Thus, to provide an interactive and updated rendering, the rendering step 845 may be continually performed, e.g., as part of a repeating rendering loop. Thus, this step 845 may be omitted from the method 800 and, instead, included as part of such other instructions. The method then proceeds to end in step 850.

It will be apparent that various data gathered or created by this method 800 may be useful for steps other than rendering. For example, simulations and other applications may make use of the surrounding 3D geometry to provide more accurate or robust output. As such, the data gather by the method 800, such as the deformed ground plane and 3D geometry, may be maintained and made available to components other than the renderers 770.

FIG. 9 illustrates an example method 900 for autosmashing an environment rendering. This method 900 may correspond to the autosmasher instructions 772 and may begin in step 905 in response to, e.g., a user indication that a subject building should be placed in a virtual environment using an autosmasher or as part of a render loop (and thus executed on a repeating basis). In step 910, the method 900 determines if this is a new autosmasher that needs to be initialized. If an autosmasher has been previously initialized, the method 900 may skip ahead to step 925. Otherwise, in step 915, the device sets the size and location of the autosmasher footprint, e.g., according to any of the previously-described methods. For example, the device may expand a footprint of the subject building out by a predetermined distance, and then crop any portions that extend into a street on the map data. Next, in step 920, the device places the building at some location within the autosmasher footprint (e.g., at a center point and at the building's default orientation). The autosmasher footprint and subject building are now initialized.

In step 925, the device flattens the ground plane within the autosmasher footprint. For example, the elevation of the ground plane (along with the lower surface elevation of the autosmasher footprint and subject building) are set to an average elevation of the area. Then, in step 930, the device removes any other 3D objects (such as building and trees) within the autosmasher footprint such that they will not be rendered by the render loop step for site rendering. These steps 925, 930 may be accomplished, for example, by directly modifying the data maintained by the site renderer 774 through execution of method 800. In some embodiments, the “removal” and “flattening” may be temporary such that, as the user modifies the location, shape, or other properties of the autosmasher, previous changes can be undone as appropriate. To accomplish this, the site renderer 774 may maintain an unmodified environment description and a modified environment description that will be used for rendering and other applications. Then, in successive executions of steps 925, 930, (e.g., as the user modifies the autosmasher footprint) the device may delete the old modified environment description, and create a new modified environment description by applying the new changes to the unmodified environment description. The method 900 may then proceed to end in step 935.

It should be apparent from the foregoing description that various example embodiments of the invention may be implemented in hardware or firmware. Furthermore, various exemplary embodiments may be implemented as instructions stored on a machine-readable storage medium, which may be read and executed by at least one processor to perform the operations described in detail herein. A machine-readable storage medium may include any mechanism for storing information in a form readable by a machine, such as a personal or laptop computer, a mobile device, a tablet, a server, or other computing device. Thus, a machine-readable storage medium may include read-only memory (ROM), random-access memory (RAM), magnetic disk storage media, optical storage media, flash-memory devices, and similar storage media.

It should be appreciated by those skilled in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in machine readable media and so executed by a computer or processor, whether or not such computer or processor is explicitly shown.

Although the various exemplary embodiments have been described in detail with particular reference to certain example aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the scope of the claims.

We claim:

1. A method for placement of a new virtual object in a virtual environment, the method comprising:
identifying a location for the new virtual object within the virtual environment;
identifying a footprint associated with the new virtual object for placement at the location;
setting a height of the virtual environment within the footprint to a height level with the footprint to produce a modified virtual environment;
placing the new virtual object within the footprint; and
rendering the modified virtual environment and new virtual object for display to a user via an interface scene.

2. The method of claim 1, wherein setting the height of the virtual environment comprises removing at least one pre-existing virtual object of the virtual environment that is located within the footprint.

3. The method of claim 2, wherein the step of rendering comprises:
animating the new virtual object virtually falling onto the location within the virtual environment; and
animating the removal of the at least one pre-existing virtual object.

4. The method of claim 1, wherein rendering the virtual environment and new virtual object comprises additionally rendering the footprint and the method further comprises:
receiving, from a user via the interface scene, a change to at least one of a dimension, size, orientation, shape, and location of the footprint to product a modified footprint; and
repeating the step of setting the height of the virtual environment with respect to the modified footprint.

5. The method of claim 1, further comprising:
receiving, from a user via the interface scene, a change to a parameter of the virtual object comprising at least one of a location and an orientation within the footprint to produce a modified parameter; and
moving the new virtual object within the footprint based on the modified parameter.

6. The method of claim 1, wherein the new virtual object is a virtual building designed by the user and the virtual environment generated based on at least one of real world map data and real world terrain data.

7. The method of claim 1, further comprising:
performing a simulation with respect to the virtual object and the modified virtual environment; and
displaying a result of the simulation to the user via the interface scene.

8. A non-transitory machine-readable medium encoded with instructions for execution by a processor for placement of a new virtual object in a virtual environment, the non-transitory machine-readable medium comprising:
instructions for identifying a location for the new virtual object within the virtual environment;
instructions for identifying a footprint associated with the new virtual object for placement at the location;
instructions for setting a height of the virtual environment within the footprint to a height level with the footprint to produce a modified virtual environment;
instructions for placing the new virtual object within the footprint; and
instructions for rendering the modified virtual environment and new virtual object for display to a user via an interface scene.

9. The non-transitory machine-readable medium of claim 8, wherein the instructions for setting the height of the virtual environment comprise instructions for removing at least one pre-existing virtual object of the virtual environment that is located within the footprint.

10. The non-transitory machine-readable medium of claim 9, wherein the instructions for rendering comprise:
instructions for animating the new virtual object virtually falling onto the location within the virtual environment; and
instructions for animating the removal of the at least one pre-existing virtual object.

11. The non-transitory machine-readable medium of claim 8, wherein the instructions for rendering the virtual environment and new virtual object comprise instructions for additionally rendering the footprint and the non-transitory machine-readable medium further comprises:
instructions for receiving, from a user via the interface scene, a change to at least one of a dimension, size, orientation, shape, and location of the footprint to product a modified footprint; and
instructions for repeating the step of setting the height of the virtual environment with respect to the modified footprint.

12. The non-transitory machine-readable medium of claim 8, further comprising:
instructions for receiving, from a user via the interface scene, a change to a parameter of the virtual object comprising at least one of a location and an orientation within the footprint to produce a modified parameter; and
instructions for moving the new virtual object within the footprint based on the modified parameter.

13. The non-transitory machine-readable medium of claim 8, wherein the new virtual object is a virtual building designed by the user and the virtual environment is generated based on at least one of real world map data and real world terrain data.

14. The non-transitory machine-readable medium of claim 8, further comprising:
instructions for performing a simulation with respect to the virtual object and the modified virtual environment; and
instructions for displaying a result of the simulation to the user via the interface scene.

15. A device for rendering a new virtual object within a virtual environment, the device comprising:
a memory storing descriptions of the new virtual object and the virtual environment; and
a processor in communication with the memory configured to:
identify a location for the new virtual object within the virtual environment;
identify a footprint associated with the new virtual object for placement at the location;
set a height of the virtual environment within the footprint to a height level with the footprint to produce a modified virtual environment;
place the new virtual object within the footprint; and
render the modified virtual environment and new virtual object for display to a user via an interface scene.

16. The device of claim 15, wherein in setting the height of the virtual environment the processor is configured to remove at least one pre-existing virtual object of the virtual environment that is located within the footprint.

17. The device of claim 16, wherein in rendering, the processor is configured to:
animate the new virtual object virtually falling onto the location within the virtual environment; and
animate the removal of the at least one pre-existing virtual object.

18. The device of claim 15, wherein in rendering the virtual environment and new virtual object, the processor is configured to additionally render the footprint and the the processor is further configured to:
receive, from a user via the interface scene, a change to at least one of a dimension, size, orientation, shape, and location of the footprint to product a modified footprint; and
repeat the step of setting the height of the virtual environment with respect to the modified footprint.

19. The device of claim 15, wherein the processor is further configured to:
receive, from a user via the interface scene, a change to a parameter of the virtual object comprising at least one of a location and an orientation within the footprint to produce a modified parameter; and
move the new virtual object within the footprint based on the modified parameter.

20. The device of claim 15, wherein the processor is further configured to:
perform a simulation with respect to the virtual object and the modified virtual environment; and
display a result of the simulation to the user via the interface scene.
